(19) United States
(12) Patent Application Publication
(10) Pub. No.: US 2005/0221568 A1
(43) Pub. Date: Oct. 6, 2005

(54) Manufacturing method of semiconductor device, semiconductor device, substrate for electro-optical device, electro-optical device, and electronic apparatus

(75) Inventors: Yukimasa Ishida, Shiojiri-shi (JP); Ryoichi Nozawa, Tatsuno-machi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/090,868

(22) Filed: Mar. 28, 2005

(30) Foreign Application Priority Data
Apr. 1, 2004 (JP) 2004-109213

(51) Int. Cl. H01L 21/336

(52) U.S. Cl. 438/303

(57) ABSTRACT

To provide a manufacturing method of a semiconductor device, which can form an LDD (lightly doped drain) structure in a self alignment manner, can suppress the length of a doped region, and can prevent characteristics from being unstabilized when oversaturated hydrogen atoms are implanted, a semiconductor device, a substrate for electro-optical device, an electro-optical device, and an electronic apparatus. A manufacturing method of a semiconductor device comprises an electrode formation step of forming an electrode above a semiconductor layer, an insulating film formation step of forming insulating films containing nitrogen on the electrode, and a heat treatment step of performing a heat treatment under an atmosphere containing vapor, oxygen, or hydrogen to form nitrogen concentration distributions in the insulating films.

### BACKGROUND

The present invention relates to a manufacturing method of a semiconductor device, a semiconductor device, a substrate for electro-optical device, an electro-optical device, and an electronic apparatus.

Generally, semiconductor devices such as thin film transistors has been applied to pixel switching elements, driver circuits, contact-type image sensors, SRAMs (Static Random Access Memories), or the like in active matrix type electro-optical devices (for example, a liquid crystal display, an organic electroluminescent display, a plasma display, or the like).

An electro-optical device having such a semiconductor device preferably uses polycrystalline silicon having high carrier mobility, rather than amorphous silicon, so as to meet acceleration of a response speed of a display and systematization of a circuit formed on a substrate.

In such a polycrystalline silicon thin film, a crystal grain boundary where a defect level is distributed with high density exists in a boundary region between crystal grains. In this case, there is a problem in that the offleak current increases due to a potentiating effect of the defect level and an electric field applied to an end of a drain region. As a countermeasure against this problem, in order to alleviate the electric field at the end of the drain region, it is effective to form an LDD (Lightly Doped Drain) structure or an offset structure. In order to form such an LDD structure, with technologies such as anisotropic etching, side walls are formed at ends of a gate electrode and doped regions having different concentrations of impurity are formed with the side walls as a mask. Further, in recent years, in order to form the LDD structure, a method in which a mask for doping is created with a photoresist and lightly doped and heavily doped regions are formed with the mask is suggested (see Patent Document 1).

On the other hand, in a manufacturing method of a semiconductor device according to the conventional art, in order to improve characteristics of a semiconductor device, a method in which a hydrogenation treatment using hydrogen plasma or the like is used is suggested. According to this method, hydrogen atoms are implanted into the polycrystalline silicon thin film to reduce defects. As a result, a semiconductor device having more stable characteristics can be manufactured.

[Patent Document 1] Japanese Unexamined Patent Application Publication No. 2003-257990

Specifically, the above-described Patent Document discloses the method in which lightly doped regions are formed with the gate electrode as a mask and heavily doped regions are formed with a photoresist having a width larger than that of the gate electrode as a mask, such that the offset structure is formed. However, in this case, there is a problem in that, when the offset structure is formed through the positioning of the photomask, depending on precision of the positioning of the mask, the lengths of the lightly doped regions in the source region and the drain region become asymmetric. That is, there is a problem in that the lengths of the lightly doped regions cannot be accurately controlled.

Further, in the hydrogenation treatment, oversaturated hydrogen atoms are implanted into the polycrystalline silicon thin film or the gate insulating film, and thus there is a problem in that large drift current occurs according to a negative gate bias voltage, as shown in the drain current-gate bias characteristic diagram in FIG. 11. Therefore, there is a problem in that a semiconductor device having stable characteristics cannot be manufactured.

The present invention has been made in consideration of the above-described problems, and it is an object of the present invention to provide a manufacturing method of a semiconductor device, which can form an LDD structure in a self alignment manner, can accurately control the lengths of doped regions, and can prevent current characteristics from being unstabilized when oversaturated hydrogen atoms are implanted, a semiconductor device, a substrate for electro-optical device, an electro-optical device, and an electronic apparatus.

### SUMMARY

In order to achieve the above-described objects, the present invention adopts the following configurations.

A manufacturing method of a semiconductor device according to the present invention comprises an electrode formation step of forming an electrode above a semiconductor layer, an insulating film formation step of forming an insulating film containing nitrogen above the semiconductor layer, and a heat treatment step of performing a heat treatment under an atmosphere containing vapor, oxygen, or hydrogen to form a nitrogen concentration distribution in the insulating film.

As such, by performing the heat treatment step, nitrogen at a portion excluding a peripheral portion of the electrode in the insulating film is removed. Further, since the heat treatment is not sufficiently performed on the peripheral portion of the electrode in the insulating film, nitrogen remains with high density. Therefore, between the peripheral portion of the electrode and the portion spaced apart from the electrode in the insulating film, regions having different nitrogen concentrations can be formed. Specifically, the nitrogen concentration at the peripheral portion of the electrode in the insulating film can be increased and the nitrogen concentration at the portion spaced apart from the electrode in the insulating film can be decreased. As such, according to the present invention, the fluctuation of the nitrogen concentration can be consecutively formed, and thus the gradient of the nitrogen concentration in the insulating film can be allowed.

The fluctuation of the nitrogen concentration can be suitably controlled by the time or temperature of the heat treatment step. Further, by adjusting the inclinations of side portions of the electrode, a desired concentration distribution can be controlled. In addition, the nitrogen concentration distribution can be formed in a self alignment manner.

Further, the manufacturing method of a semiconductor device further comprises, after the heat treatment step, a hydrogenation treatment step of implanting hydrogen atoms into the semiconductor layer.

As such, by performing the hydrogenation treatment step, hydrogen atoms are injected into the insulating film from a surface thereof. As described above, the nitrogen concentration distribution is formed in the insulating film, and thus the hydrogen-atoms pass through the insulating film to be implanted into the semiconductor layer according to the nitrogen concentration distribution. Here, the portion where the nitrogen concentration is high hardly transmits the hydrogen atoms and the portion where the nitrogen concentration is low easily transmits the hydrogen atoms. Thus, the hydrogen atoms can be implanted into the semiconductor layer with the concentration distribution according to the nitrogen concentration distribution.

Therefore, as described above, the nitrogen concentration at the peripheral portion of the electrode in the insulating film is high and the nitrogen concentration at the portion spaced apart from the electrode is low. Thus, the hydrogen atoms can be implanted with a low concentration into a peripheral portion of a channel region of the semiconductor layer just below the electrode. Further, the hydrogen atoms can be implanted with a high concentration into the portion of the semiconductor layer spaced apart from the channel region. Then, the fluctuation of a hydrogen concentration can be consecutively formed in such a manner, and thus the gradient of the hydrogen concentration in the semiconductor layer can be allowed. In addition, the defect density distribution the semiconductor layer is formed according to the hydrogen concentration distribution. Thus, the defect density at the peripheral portion of the channel region can be increased and the defect density at the portion spaced apart from the channel region can be decreased.

As such, according to the present invention, the hydrogen concentration distribution and the defect density distribution can have the gradient in the self alignment manner.

Further, in such a manner, the hydrogen atoms are implanted into the semiconductor layer, and thus a high-resistance region can be formed in the self alignment manner between the channel region of the semiconductor layer disposed just below the electrode and the source region or drain region adjacent to the channel region. As a result, the offleak current caused by electric field concentration at ends of the drain region can be reduced. In addition, according to the present invention, the high-resistance (defect) region can be formed in the self alignment manner, and thus a variation in characteristic of the semiconductor device can be prevented from being caused. Further, a change in threshold value caused by the generation of hot electrons can be prevented.

Further, the high nitrogen concentration region is formed above the semiconductor layer through the above-described steps, and thus the hydrogen atoms (terminating a dangling bond state) in the semiconductor layer are hardly separated from the semiconductor layer, thereby obtaining a blocking effect. As a result, the semiconductor device having more stable reliability can be implemented. Further, if the gate insulating film is formed between the electrode and the semiconductor layer, the oversaturated hydrogen atoms can be prevented from being implanted into the gate insulating film at the time of the hydrogenation treatment. In particular, in a P-type semiconductor device, when a negative bias voltage is applied to the gate electrode, the threshold value can be prevented from being enhanced due to a hole implantation effect into the gate insulating film. Therefore, operational reliability of CMOS circuits can be enhanced.

Further, in the manufacturing method of a semiconductor device, the hydrogenation treatment step is a hydrogen plasma treatment or hydrogen diffusion treatment.

Here, the hydrogen plasma treatment is a method in which, in a state that a hydrogen gas is supplied into a vacuum chamber, a high frequency power is supplied to excite and resolve the hydrogen gas and the hydrogen atoms are implanted into the semiconductor layer. Then, hydrogen can be implanted into the semiconductor layer by means of the hydrogen plasma action. Further, the hydrogen diffusion treatment is a method in which, in a state that a material containing the hydrogen atoms is formed on the insulating film, the heat treatment is performed and hydrogen in the material is diffused and implanted into the semiconductor layer. Then, hydrogen can be implanted into the semiconductor layer by means of the hydrogen diffusion action.

Further, the manufacturing method of a semiconductor device further comprises, after the electrode formation step, an impurity implantation step of implanting an impurity into the semiconductor layer.

In the impurity implantation step, the electrode may be used as a mask, a photoresist may be used as a mask, and side wall portions formed on side portions of the electrode may be used as a mask. By performing the impurity implantation step on the semiconductor layer, the impurity regions and the channel region can be formed in the semiconductor layer. Further, in the semiconductor layer, by performing the above-described steps, the hydrogen concentration distribution and the defect density distribution can be formed according to the nitrogen concentration distribution in the insulating film. Therefore, in the insulating film having the impurity regions and the channel region, the defect density distribution can be formed.

As such, according to the present invention, since the semiconductor device having the defect density distribution, the channel region, and the impurity regions can be manufactured, the above-described advantages can be further promoted. Specifically, the offleak current caused by the electric field concentration at the ends of the drain region can be further reduced. Further, a variation in characteristic of the semiconductor device can be suppressed. Further, a change in threshold value caused by the generation of hot electrons can be suppressed. As a result, the semiconductor device having more stable reliability can be implemented and operational reliability of CMOS circuits can be further enhanced.

Further, in the manufacturing method of a semiconductor device, the impurity implantation step implants a first concentration of impurity and a second concentration of impurity into the semiconductor layer to respectively form a first concentration impurity region adjacent to a channel region of the semiconductor layer and a second concentration impurity region adjacent to the first concentration impurity region. Here, the first concentration is relatively lower than the second concentration.

As such, by implanting the first concentration of impurity and the second concentration of impurity into the semiconductor layer, the first concentration impurity region adjacent to the channel region and the second concentration impurity region adjacent to the first concentration impurity region can be formed. Further, by performing the above-described steps on the semiconductor layer having the above-described regions, the hydrogen concentration distribution is formed according to the nitrogen concentration distribution in the insulating film and the defect density distribution is formed according to the hydrogen concentration distribution. Therefore, different defect densities can be imparted to the respective regions of the semiconductor layer which has the first concentration impurity region, the second concentration impurity region, and the channel region. That is, according to the present invention, the channel region having high defect density, the first concentration impurity region having high defect density, and the first concentration impurity region having low defect density, and the second concentration impurity region having low defect density can be formed in the semiconductor layer.

Further, since the semiconductor device having the channel region, the first concentration impurity region, and the second concentration impurity region can be manufactured, the above-described advantages can be further promoted. That is, the offleak current caused by electric field concentration at the ends of the drain region can be further reduced. Further, the variation in characteristic of the semiconductor device can be suppressed. Further, the change in threshold value caused by the generation of hot electrons can be further suppressed. As a result, the semiconductor device having more stable reliability can be implemented and operational reliability of the CMOS circuits can be further enhanced.

Further, the manufacturing method of a semiconductor device further comprises, after the heat treatment step, a side wall portion formation step of etching the insulating film to form side wall portions adjacent to the electrode, and an impurity implantation step of implanting an impurity into the semiconductor layer with the side wall portions as a mask. Here, since the nitrogen concentration distribution is formed in the insulating film as described above, the quality of the insulating film, in particular, etching selectivity consecutively changes according to the nitrogen concentration distribution. Specifically, when etching is performed on the insulating film under the same condition, an etching rate of a portion where the nitrogen concentration is high becomes slow and an etching rate of a portion where the nitrogen concentration is low becomes fast. That is, the amount of etching at the peripheral portion of the electrode becomes small and the amount of etching at the portion spaced apart from the electrode becomes large. Therefore, by performing the etching step, while leaving the insulating film at the peripheral portion of the electrode, the insulating film at the portion spaced apart from the electrode can be removed. Accordingly, the side wall portions having inclinations adjacent to the electrode can be formed. In addition, the impurities are implanted into the semiconductor layer with the resultant side wall portions as a mask, and thus the impurity regions can be formed in the semiconductor layer according to the shapes of the side wall portions in the self alignment manner.

Further, since the impurity regions are formed in the self alignment manner as described above, the offleak current caused by the electric field concentration at the ends of the drain region can be reduced. Accordingly, according to the present invention, the high-resistance (defect) region can be formed in the self alignment manner, and thus the variation in characteristic of the semiconductor device can be prevented from being caused.

Further, in the manufacturing method of a semiconductor device, the impurity implantation step implants a first concentration of impurity and a second concentration of impurity into the semiconductor layer according to the shapes of the side wall portions. Here, the side wall portions hardly transmit the impurity at the peripheral portion of the electrode and easily transmit the impurity as they go away from the electrode. Thus, the impurity is implanted with a low concentration into the peripheral portion of the channel region just below the electrode. Further, the impurity is implanted with a high concentration as going away from the channel region. Thus, the first concentration impurity region and the second concentration impurity region having different concentrations of impurity can be formed according to the shapes of the side wall portions. Therefore, according to the present invention, the first concentration impurity region and the second concentration impurity region can be formed in the self alignment manner.

Further, since the first concentration impurity region and the second concentration impurity region are formed in the self alignment manner as described above, the offleak current caused by the electric field concentration at the ends of the drain region can be reduced. Therefore, according to the present invention, the high-resistance (defect) region can be formed in the self alignment manner, and thus the variation in characteristic of the semiconductor device can be prevented from being caused.

Further, in the manufacturing method of a semiconductor device, the electrode is one of a gate electrode and a source or drain electrode. Here, when the electrode is the gate electrode, a semiconductor device having a top gate structure in which the gate electrode is arranged on the semiconductor layer via the gate insulating film can be manufactured. Further, when the electrode is the source or drain electrode, a semiconductor device having a bottom gate structure in which the gate electrode is provided below the semiconductor layer and the source or drain electrode is arranged on the semiconductor layer via the gate insulating film can be manufactured.

Further, a semiconductor device according to the present invention comprises, above a semiconductor layer, an electrode and an insulating film containing nitrogen. Further, a nitrogen concentration in the insulating film is symmetrically distributed into both side portions of the electrode. Further, in the semiconductor device, the nitrogen concentration in the insulating film may be high in a peripheral portion of the electrode and low in a portion spaced apart from the electrode. Then, the nitrogen concentration in the insulating film may be consecutively distributed.

Such a semiconductor device is manufactured by using the above-described manufacturing method of a semiconductor device. Therefore, when the heat treatment is performed on the insulating film containing nitrogen as described above, nitrogen remains at the portion where the heat treatment is not sufficiently performed. Then, since nitrogen remains in the self alignment manner, the concentration distribution can be symmetrically formed at both sides of the electrode. Further, in the semiconductor device, the nitrogen concentration can be increased at the peripheral portion of the electrode and can be decreased at the portion spaced apart from the electrode. In addition, the concentration distribution can be consecutively formed.

Further, a substrate for electro-optical device according to the present invention comprises, on a substrate, the above-described semiconductor device. According to this configuration, the offleak current caused by the electric field concentration at the ends of the drain region of the semiconductor device can be reduced. Further, the variation in characteristic of the semiconductor device can be suppressed and the change in threshold value caused by the generation of hot electrons can be further suppressed. Further, the substrate for electro-optical device having more stable reliability can be implemented and operational reliability of the CMOS circuits can be enhanced.

Further, an electro-optical device according to the present invention comprises the above-described substrate for electro-optical device. According to this configuration, the substrate for electro-optical device having stable reliability can be implemented and operational reliability of the CMOS circuits can be enhanced.

Further, an electronic apparatus according to the present invention comprises the above-described electro-optical device. As the electronic apparatus, for example, an information processing device such as a cellular phone, a mobile information terminal, a watch, a word processor, a personal computer or the like may be exemplified. Further, a television having a large-scaled display screen, a large-scaled monitor, or the like may be exemplified. As described above, the electro-optical device according to the present invention can be adopted for a display unit of the electronic apparatus, and thus the electronic apparatus comprising the display unit having high operational reliability can be provided.

### BRIEF DESCRIPTION OF THE DRAWINGS

FIGS. 1A-1H are diagrams illustrating a manufacturing method of a semiconductor device according to a first embodiment of the present invention;

FIGS. 2A-2C are diagrams illustrating the semiconductor device according to the first embodiment of the present invention;

FIGS. 3A-3I are diagrams illustrating a manufacturing method of a semiconductor device according to a second embodiment of the present invention;

FIGS. 4A-4C are diagrams illustrating the semiconductor device according to the second embodiment of the present invention;

FIGS. 5A-5H are diagrams illustrating a manufacturing method of a semiconductor device according to a third embodiment of the present invention;

FIGS. 6A-6C are diagrams illustrating the semiconductor device according to the third embodiment of the present invention;

FIG. 7 is an equivalent circuit diagram of an organic EL device as an electro-optical device according to the present invention;

FIG. 8 is a plan view of the organic EL device as the electro-optical device according to the present invention;

FIG. 9 is an expanded cross-sectional view of essential parts of the organic EL device as the electro-optical device according to the present invention;

FIGS. 10A-10C are diagrams showing electronic apparatuses according to the present invention;

FIG. 11 is a diagram illustrating a prior art.

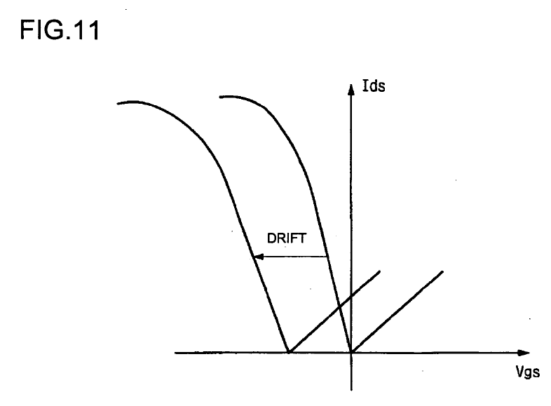

### DETAILED DESCRIPTION OF EMBODIMENTS

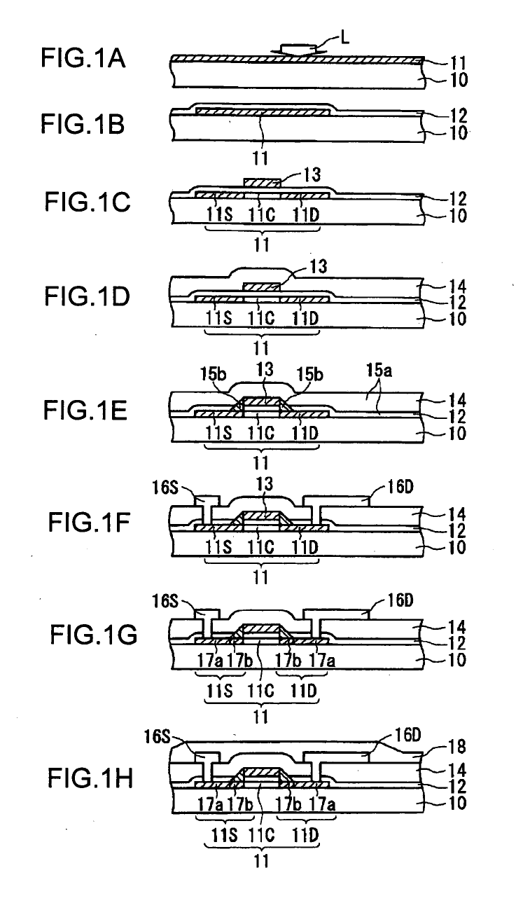

Hereinafter, a manufacturing method of a semiconductor device, a semiconductor device, a substrate for electro-optical device, an electro-optical device, and an electronic apparatus will be described with reference to FIGS. 1(a) to FIGS. 10(c).

Embodiments just show one aspect of the present invention, and it is not intended to limit the present invention. The embodiments can be modified within the technical scope without departing from the spirit of the present invention. Moreover, in the drawings, each layer or each member has a different reduced scale so that each layer or each member can be fully recognized.

### First Embodiment of Manufacturing Method of Semiconductor Device

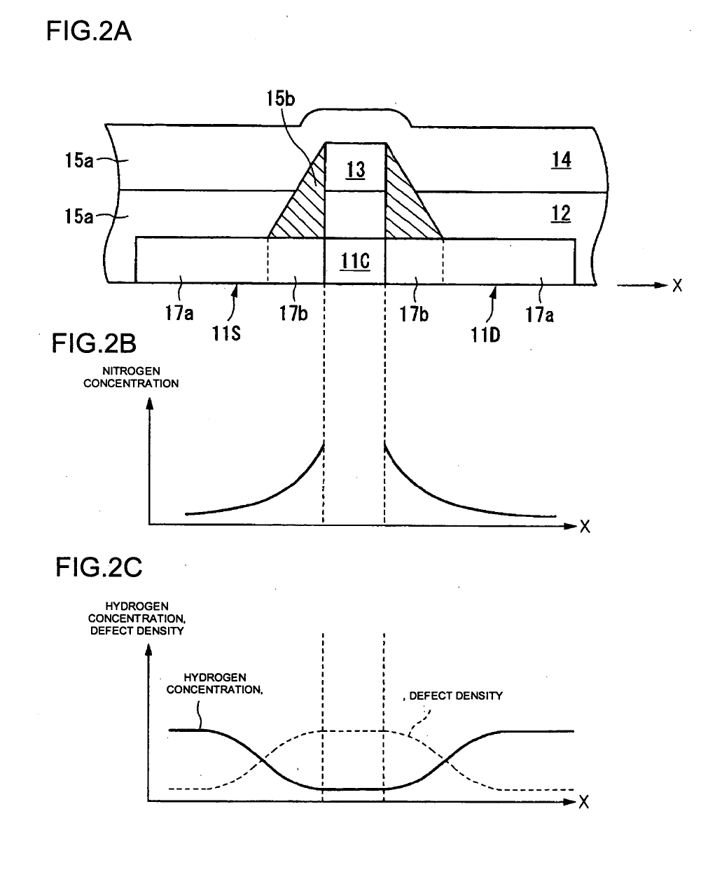

A first embodiment of a manufacturing method of a semiconductor device will be described with reference to FIGS. 1(a) to 2(c).

FIGS. 1(a) to 1(h) are process views illustrating the manufacturing method of a semiconductor device, which are expanded cross-sectional views of a semiconductor device. FIG. 2(a) is an expanded cross-sectional view of the semiconductor device which shows a peripheral portion of a gate electrode 13, FIG. 2(b) is a diagram showing a nitrogen concentration distribution corresponding to FIG. 2(a), and FIG. 2(c) is a diagram illustrating a hydrogen concentration distribution and a defect density distribution of a polycrystalline silicon film corresponding to FIG. 2(a).

First, as shown in FIG. 1(a), a base protective film is formed on a glass substrate 10 and a polycrystalline silicon film (semiconductor layer) 11 is formed on the base protective film.

Prior to forming the semiconductor layer 11, the glass substrate 10 is cleaned by means of ultrasonic cleaning methods and then the base protective film made of an insulating film such as a silicon oxide or the like is film-formed on an entire surface of the glass substrate 10 under a condition that a temperature of the glass substrate 10 is in a range of from 150 to 450° C. Specifically, the base protective film is film-formed to have a thickness of less than 10 μm (for example, about 500 nm) by means of plasma CVD (Chemical Vapor Deposition) methods or the like. In this step, a mixed gas of monosilane and dinitrogen oxide, TEOS (tetraethoxysilane, Si(OC₂H₅)₄) and oxygen, monosilane and ammonia, disilane and ammonia, or the like may be suitably used as a raw gas. The base protective film serves as a buffer layer or a barrier layer.

Further, on the entire surface of the glass substrate 10 on which the base protective is formed under a condition that the temperature of the glass substrate 10 is in a range of from 150 to 450° C., an amorphous silicon film is film-formed to have a thickness of, for example, 30 to 100 nm by means of the plasma CVD methods or the like. In this step, silane or monosilane may be suitably used as a raw gas.

Next, by irradiating excimer laser light L (having a wavelength of 308 nm at the time of a XeCl excimer laser or a wavelength of 249 m at the time of a KrF excimer laser) onto the amorphous silicon film, laser annealing is performed, such that the polycrystalline silicon film 11 is generated.

Next, the polycrystalline silicon film 11 is patterned in the shape of an active layer to be formed by means of photolithography methods. Specifically, after a photoresist is coated on the polycrystalline silicon film 11, the photoresist is exposed and developed, the polycrystalline silicon film 11 is etched, and then the photoresist is removed, such that the polycrystalline silicon film 11 is patterned. Moreover, while patterning the amorphous silicon film, laser annealing may be performed to form the polycrystalline silicon film. As a material for the semiconductor layer, amorphous silicon or polycrystalline silicon which is crystallized by means of a heat treatment may be used.

Next, as shown in FIG. 1(b), a gate insulating film (an insulating film) 12 is formed on the polycrystalline silicon film 11 (a gate insulating film formation step).

In order to form the gate insulating film 12, the gate insulating film 12 made of a silicon oxide and/or a silicon nitride is film-formed on the entire surface of the glass substrate 10 including the polycrystalline silicon film 11 under a temperature condition of 350° C. or less. The resultant film mainly contains the silicon oxide and has a nitrogen concentration of 5×10²¹ atom/cm³ or more. Preferably, the nitrogen concentration is in a range of from about 1×10²⁰ atom/cm³ to about 1×10²¹ atom/cm³ and the thickness of the gate insulating film 12 is in a range of from about 5 nm to about 200 nm. In this step, a mixed gas of monosilane and dinitrogen oxide, silane and ammonia, and so on may be used as a raw gas. By adjusting a mixture ratio of such a mixed gas, a nitrogen concentration in the gate insulating film 12 can be increased. As for the gate insulating film 12, it is not necessary to increase the nitrogen concentration. Thus, the gate insulating film 12 may be formed with the mixed gas of TEOS (tetraethoxysilane, Si(OC₂H₅)₄) and oxygen.

Next, as shown in FIG. 1(c), a gate electrode (electrode) 13 is formed (an electrode formation step). In order to form the gate electrode 13, a conductive material made of a metal material such as aluminum, tantalum, molybdenum or the like, or an alloy mainly containing one of the above-described metal materials is film-formed on the entire surface of the glass substrate 10 including the gate insulating film 12 by means of a sputtering method and is patterned by means of the photolithography method, such that the gate electrode 13 having a thickness of 300 to 800 nm is formed. Specifically, after a photoresist is coated on the glass substrate 10 on which the conductive material is film-formed, the photoresist is exposed and developed, the conductive material is etched, and the photoresist is removed, such that the conductive material is patterned and the gate electrode 13 is formed.

Next, an ion implantation into the polycrystalline silicon film 11 is performed (an impurity implantation step).

In order to perform the ion implantation, a resist mask wider than the gate electrode 13 is formed, and then high-concentration impurity ions (phosphorus ions) are doped with a dose amount of about 0.1×10¹⁵ to about 10×10¹⁵/cm², such that a source region (an impurity region) 11S and a drain region (an impurity region) 11D are formed. Then, at a portion disposed just below the gate electrode 13, a channel region 11C is formed.

Next, as shown in FIG. 1(d), an interlayer insulating film (insulating film) 14 is formed (an insulating film formation step).

In order to form the interlayer insulating film 14, the interlayer insulating film 14 made of a silicon oxynitride film is film-formed on the surface of the gate electrode 13 by using the CVD method or the like. Specifically, by using a mixed gas of monosilane and dinitrogen oxide or disilane and ammonia as a raw gas and by suitably setting flow ratios of the respective gases, the silicon oxynitride film having a predetermined nitrogen concentration is obtained. The resultant film mainly contains the silicon oxide and has the nitrogen concentration of 5×10²¹ atom/cm³ or more. Preferably, the nitrogen concentration is in a range of from 1×10²⁰ atom/cm³ to 1×10²¹ atom/cm³. Further, the thickness of the interlayer insulating film 14 is preferably in a range of from 400 nm to 1200 nm.

Next, as shown in FIG. 1(e), the nitrogen concentration distribution is formed in the gate insulating film 12 and the interlayer insulating film 14.

In order to form the nitrogen concentration distribution in the gate insulating film 12 and the interlayer insulating film 14, an annealing treatment (a heat treatment step) is adopted. In this case, the annealing treatment is performed under an atmosphere containing vapor, oxygen, or hydrogen. Specifically, the substrate 10 on which the semiconductor layer 12 is formed is arranged within a chamber of an annealing device and high-temperature vapor, oxygen, or hydrogen is supplied into the chamber which is set at a predetermined pressure, such that the annealing treatment is conducted.

Here, the nitrogen concentration distribution in the gate insulating film 12 and the interlayer insulating film 14 after the annealing treatment will be described with reference to FIGS. 2(a) and 2(b). If the annealing treatment is conducted as described above, in a first region 15a which is the portion spaced apart from the gate electrode 13, the silicon oxynitride film is oxidized and the gate insulating film 12 and the interlayer insulating film 14 having a low nitrogen concentration are formed, such that a low nitrogen concentration region is formed. The nitrogen concentration in the low nitrogen concentration region becomes 5×10²¹ atom/cm³ or less. Thus, in a subsequent hydrogenation treatment step, hydrogen can be effectively implanted. On the other hand, in a second region 15b which is the peripheral portion of the gate electrode 13 and where the annealing treatment does not reach, the nitrogen concentration does not almost change even when the annealing treatment is conducted, such that a high nitrogen concentration region is formed. Since this region hardly transmits hydrogen ions, it serves as a mask in the subsequent hydrogenation treatment step. Further, the annealing treatment plays a role in reducing defects (dangling bonds) included in the gate insulating film 12, the interlayer insulating film 14, and the semiconductor layer 11. Therefore, by means of the annealing treatment, the gate insulating film 12 and the interlayer insulating film 14 having the nitrogen concentration distribution which includes the first region (low nitrogen concentration) 15a and the second region (high nitrogen concentration) 15b are formed. Further, as shown in FIG. 2(b), in the gate insulating film 12 and the interlayer insulating film 14, the fluctuation of the nitrogen concentration is consecutively distributed from the second region 15b toward the first region 15a. In addition, the nitrogen concentration distribution is symmetrically formed at both sides of the gate electrode 13.

Moreover, for example, the gate insulating film 12 and the interlayer insulating film 14 may be formed by means of the CVD method of the temperature of about 300° C. and the annealing treatment may be conducted under the same condition of about 300° C. In this case, the film formation step and the annealing step of the gate insulating film can be conducted within the same chamber, and thus a simple and consecutive process can be conducted, for example, by switching an influent gas.

Further, as shown in FIG. 2(b), the desired nitrogen concentration distribution can be determined according to the time or temperature of the annealing step. Further, by adjusting inclinations of side portions of the gate electrode 13, the desired concentration distribution can be determined.

Next, as shown in FIG. 1(f), a source electrode 16S and a drain electrode 16D are formed.

In this step, a resist mask having a predetermined pattern is formed and dry etching is performed on the interlayer insulating film 14 via the resist mask, such that contact holes are respectively formed in portions of the interlayer insulating film 14 corresponding to a source region and a drain region. Then, a conductive material made of a metal material such as aluminum, titanium, titanium nitride, tantalum, or molybdenum, or an alloy mainly containing one of the above-described metal materials or the like is film-formed on the entire surface of the interlayer insulating film 14 by means of the sputtering method or the like and is patterned by the photolithography method, such that the source electrode 16S and the drain electrode 16D each having a thickness of 400 to 800 nm are formed. Specifically, after a photoresist is coated on the glass substrate 10 on which the conductive material is film-formed, the photoresist is exposed and developed, the conductive material is etched by dry etching, and the photoresist is removed, such that the conductive material is patterned and the source electrode 16S and the drain electrode 16D are formed.

Next, as shown in FIG. 1(g), the hydrogenation treatment step is performed.

In this step, a hydrogen plasma treatment is performed on the gate insulating film 12 and the interlayer insulating film 14 having the nitrogen concentration distribution, such that the hydrogen atoms are implanted into the polycrystalline silicon film 11.

The hydrogen plasma treatment is a method in which, in a state that a hydrogen gas is supplied into a vacuum chamber, a high frequency power is supplied to excite and resolve the hydrogen gas and the hydrogen atoms are implanted into the polycrystalline silicon film 11. Then, hydrogen can be implanted into the polycrystalline silicon film 11 by means of the hydrogen plasma action.

Moreover, the hydrogenation treatment step is not limited to the plasma treatment. For example, a hydrogen diffusion treatment may be conducted. This is a method in which, in a state that a material containing the hydrogen atoms is formed on the interlayer insulating film 14, the heat treatment is performed and hydrogen in the material is diffused and implanted into the polycrystalline silicon film 11. Then, hydrogen can be implanted into the polycrystalline silicon film 11 by means of the hydrogen diffusion action.

Here, a hydrogen concentration distribution and a defect density distribution in the polycrystalline silicon film 11 after the hydrogenation treatment will be described with reference to FIGS. 2(a) and 2(c).

As described above, if the hydrogen atoms are implanted via the gate insulating film 12 and the interlayer insulating film 14 having the nitrogen concentration distribution, in the high nitrogen concentration region of the second region 15b, transmittance of hydrogen is low and hydrogen ions are hardly implanted into the polycrystalline silicon film 11. Thus, in the polycrystalline silicon film 11 corresponding to the second region 15b, the termination of the dangling bond is not performed and the defect density is increased, such that a high-resistance region (a defect region) 17b is formed. On the other hand, in the low nitrogen concentration region of the first region 15a, transmittance of hydrogen is high and the hydrogen ions are easily implanted into the polycrystalline silicon film 11. Thus, in the polycrystalline silicon film 11 corresponding to the first region 15a, the termination of the dangling bond is performed and the defect density is decreased, such that a low-resistance region 17a is formed. Therefore, as shown in FIG. 2(c), within the polycrystalline silicon film 11, the hydrogen concentration distribution and the defect density distribution according to the hydrogen concentration distribution are generated.

Further, the termination of the dangling bond in the polycrystalline silicon film 11 is made and simultaneously damages against the polycrystalline silicon film 11, an interface between the polycrystalline silicon film 11 and the gate insulating film 12, or the gate insulating film 12, which are generated when dry etching is conducted in the source electrode 16S and the drain electrode 16D, are also recovered. Further, the nitrogen concentration distribution within the gate insulating film 12 and the interlayer insulating film 14 is formed in the self alignment manner according to the shape of the gate electrode 13, and thus the high-resistance region 17b and the low-resistance region 17a are formed in the self alignment manner with respect to the source region 11S and the drain region 11D.

Next, as shown in FIG. 1(h), a passivation film 18 is formed. Accordingly, the manufacturing process of the semiconductor device is completed.

In this step, the passivation film 18 made of a silicon nitride film is formed to cover the source electrode 16S and the drain electrode 16D. The passivation film 18 plays a role in allowing hydrogen to remain in the hydrogenated polycrystalline silicon film 11. Therefore, for the passivation film 18, the silicon nitride film having low gas transmittance is preferably used.

Moreover, in the present embodiment, after the interlayer insulating film 14 is formed, the annealing treatment is conducted to form the nitrogen concentration distribution, but the present invention is not limited to the annealing treatment step which is conducted just after the interlayer insulating film 14 is formed. For example, after the source electrode 16S and the drain electrode 16D are formed, the annealing treatment may be conducted to form the nitrogen concentration distribution.

As described above, in the present embodiment, the annealing step is conducted on the interlayer insulating film 14 containing nitrogen and the gate insulating film 12, and thus the nitrogen concentration distribution in the interlayer insulating film 14 and the gate insulating film 12 can be formed. Specifically, the nitrogen concentration can be increased at the peripheral portion of the gate electrode 13 and can be decreased at the portion spaced apart from the gate electrode 13. Then, the fluctuation of the nitrogen concentration can be consecutively formed, and thus a gradient of the nitrogen concentration in the insulating film can be allowed. Further, the nitrogen concentration distribution can be formed in the self alignment manner.

Further, by performing the hydrogenation treatment step, the hydrogen atoms can be implanted into the polycrystalline silicon film 11 according to the nitrogen concentration distribution in the interlayer insulating film 14 and the gate insulating film 12. The hydrogen atoms can be implanted with a low concentration into a peripheral portion of the channel region 11C and can be implanted with a high concentration into the source region 11S and the drain region 11D which are spaced apart from the channel region 11C. And then, the fluctuation of the hydrogen concentration can be consecutively formed as described above, and thus the gradient of the hydrogen concentration in the polycrystalline silicon film 11 can be allowed. Then, the defect density distribution of the polycrystalline silicon film 11 can be formed according to the hydrogen concentration distribution. Further, the hydrogen concentration distribution and the defect density distribution can be formed in the self alignment manner.

Further, by implanting the hydrogen atoms into the polycrystalline silicon film 11 as described above, the high-resistance region 17b can be formed in the self alignment manner between the channel region 11C and the source region 11S or the drain region 11D, and thus the offleak current caused by electric field concentration at ends of the drain region can be reduced. Further, the high-resistance region 17b is formed in the self alignment manner, and it has an advantage in that the variation in characteristic of the semiconductor device can be prevented from being caused. Further, the change in threshold value caused by the generation of hot electrons can be prevented. Further, by providing the high nitrogen concentration region above the polycrystalline silicon film 11, the hydrogen atoms (terminating the dangling bond states) of the polycrystalline silicon film 11 are hardly separated from the polycrystalline silicon film 11, thereby obtaining a blocking effect. As a result, the semiconductor layer having more stable reliability can be implemented.

Further, oversaturated hydrogen atoms can be prevented from being implanted into the gate insulating film 12 when the hydrogenation treatment. Thus, in particular, when a negative bias voltage is applied to the gate electrode of a P-type semiconductor device, the threshold value can be prevented from being enhanced due to a hole implantation effect into the gate insulating film 12. Therefore, operational reliability of CMOS circuits can be enhanced.

Further, since the source region 11S and the drain region 11D are formed in the polycrystalline silicon film 11 by means of the impurity implantation step, the gradient of the hydrogen concentration can be formed between the source and drain regions 11S and 11D and the channel region 11C and the defect density distribution can be formed according to the gradient of the hydrogen concentration. Therefore, the defect density can be increased as approaching the channel region 11C and can be decreased as going away from the channel region 11C. Further, in the source and drain regions 11S and 11D of the polycrystalline silicon film 11, the concentration gradient having a consecutive fluctuation of the hydrogen concentration and the gradient of the defect density distribution according to the concentration gradient can be formed.

### Second Embodiment of Manufacturing Method of Semiconductor Device

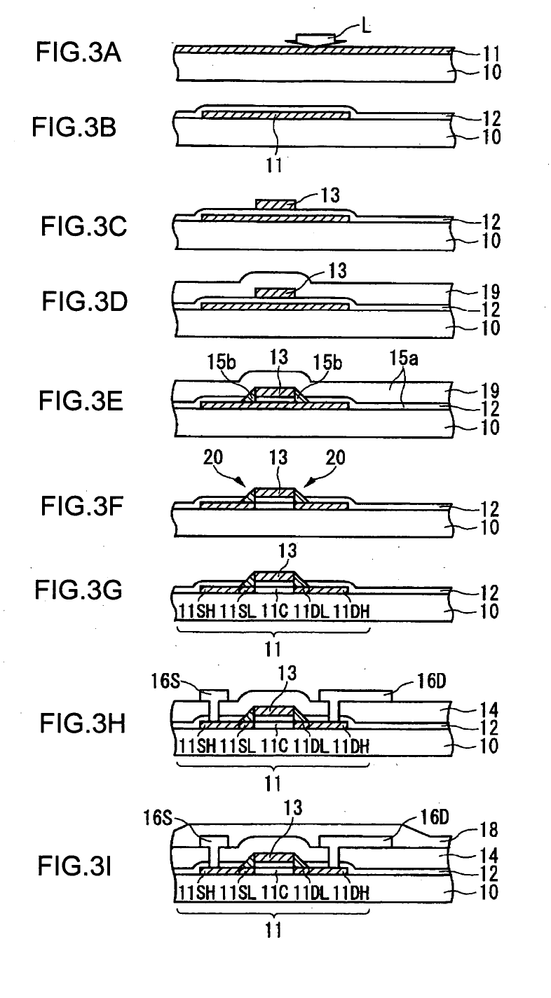

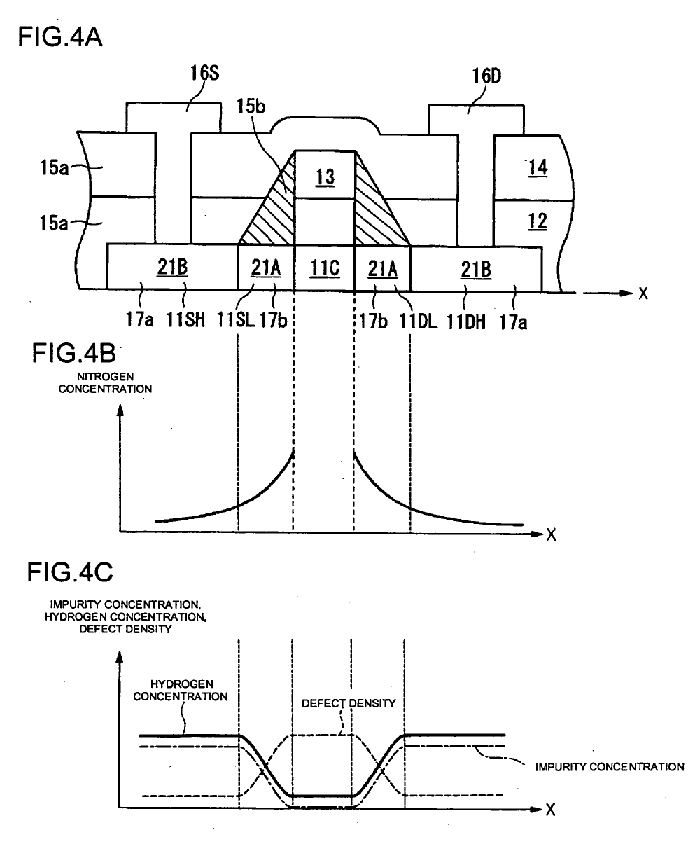

A second embodiment of the manufacturing method of a semiconductor device will be described with reference to FIGS. 3(a) to 4(c).

FIGS. 3(a) to 3(i) are process views illustrating the manufacturing method of a semiconductor device, which are expanded cross-sectional views of a semiconductor device. FIG. 4(a) is an expanded cross-sectional view of the semiconductor device which shows a peripheral portion of the gate electrode 13, FIG. 4(b) is a diagram showing a nitrogen concentration distribution corresponding to FIG. 4(a), and FIG. 4(c) is a diagram illustrating a hydrogen concentration distribution, a defect density distribution, and an impurity concentration distribution of a polycrystalline silicon film corresponding to FIG. 4(a). Moreover, in the present embodiment, different portions from the above-described first embodiment will be described. Further, the same elements are represented by the same reference numerals and the descriptions of the same elements will be omitted.

First, as shown in FIG. 3(a), the base protective film is formed on the glass substrate 10 and the polycrystalline silicon film (semiconductor layer) 11 is formed on the base protective film.

Next, as shown in FIG. 3(b), the gate insulating film 12 is formed on the polycrystalline silicon film 11. In order to form the gate insulating film 12, the gate insulating film 12 made of a silicon oxide and/or a silicon nitride is film-formed on the entire surface of the glass substrate 10 including the polycrystalline silicon film 11 under a temperature condition of 350° C. or less. The resultant film mainly contains the silicon oxide and has a nitrogen concentration of 5×10²¹ atom/cm³ or more. Preferably, the nitrogen concentration is in a range of from about 1×10²⁰ atom/cm³ to about 1×10²¹ atom/cm³ and the thickness of the gate insulating film 12 is in a range of from about 5 nm to about 200 nm. By doing so, the gate insulating film 12 is hardly etched at the time of a subsequent side wall formation step, such that side walls can be selectively formed.

Next, as shown in FIG. 3(c), the gate electrode (electrode) 13 is formed.

Next, as shown in FIG. 3(d), an oxynitride film 19 is formed.

In order to form the oxynitride film 19, the oxynitride film 19 made of the silicon oxynitride film is film-formed on the surface of the gate electrode 13 by using the CVD method or the like. Specifically, by using a mixed gas of monosilane and dinitrogen oxide or disilane and ammonia as a raw gas and by suitably setting flow ratios of the respective gases, the silicon oxynitride film having a predetermined nitrogen concentration is obtained. The resultant film mainly contains the silicon oxide and has a nitrogen concentration of 5×10²¹ atom/cm³ or more. Preferably, the nitrogen concentration is in a range of from about 1×10²⁰ atom/cm³ to about 1×10²¹ atom/cm³. Further, the thickness of the interlayer insulating film 14 is in a range of from about 400 nm to about 1200 nm.

Next, as shown in FIG. 3(e), the nitrogen concentration distribution in the gate insulating film 12 and the oxynitride film 19 is formed.

In order to form the nitrogen concentration distribution in the gate insulating film 12 and the oxynitride film 19, the annealing treatment is adopted. In this case, the annealing treatment is performed under an atmosphere including vapor, oxygen, or hydrogen. In the first region 15a where the annealing treatment reaches regardless of the gate electrode 13, the oxynitride film is oxidized, such that the low nitrogen concentration region having the nitrogen concentration of 5×10²¹ atom/cm³ or less can be formed in the gate insulating film 12 and the oxynitride film 19. Thus, in the subsequent hydrogenation treatment step, hydrogen is easily and effectively implanted. On the other hand, in the second region 15b where the annealing treatment does not reach by means of the gate electrode 13, the nitrogen concentration does not changes by means of the annealing treatment, and thus the high nitrogen concentration region is formed. This region hardly transmits the hydrogen atoms and serves as a mask at the time of the subsequent hydrogenation treatment.

Next, as shown in FIG. 3(f), the side walls (side wall portions) 20 are formed (a side wall portion formation step).

In the side wall formation step, the high nitrogen concentration region (the second region) 15b and the low nitrogen concentration region (the first region) 15a have different etching rates, and thus the low nitrogen concentration region 15a can be selectively etched. Thus, the side walls 20 made of the high nitrogen concentration region 15b can be formed at the peripheral portion of the gate electrode 13. For example, by performing wet etching with fluoric acid as an etching solution, the side walls can be selectively formed.

Next, as shown in FIG. 3(g), an ion implantation into the polycrystalline silicon film 11 is performed (an impurity implantation step).

In order to perform the ion implantation, the high-concentration impurity ions (phosphorus ions) are doped with a dose amount of about 0.1×10¹⁵ to about 10×10¹⁵/cm², with the gate electrode 13 and the side walls 20 as a mask. At this time, while the impurity with the amount corresponding to the above-described dose amount are doped into the polycrystalline silicon film 11 above which the side walls 20 are not formed, the impurity with the amount lower than the dose amount are doped into the polycrystalline silicon film 11 in a periphery of the gate electrode 13 with the side walls 20 formed thereon since the side walls 20 are present. Thus, a low-concentration source region (a first concentration impurity region) 11SL, a low-concentration drain region (a first concentration impurity region) 11DL, a high-concentration source region (a second concentration impurity region) 11SH, and a high-concentration drain region (a second concentration impurity region) 11DH are formed. Further, between the low-concentration source region 11SL and the low-concentration drain region 11DL, the channel region 11C is formed. Here, the side walls 20 are formed in the self alignment manner according to the shape of the gate electrode 13, and thus the low-concentration source region 11SL and the low-concentration drain region 11DL are formed in the self alignment manner.

Next, as shown in FIG. 3(h), the interlayer insulating film 14 is formed.

In order to form the interlayer insulating film 14, the interlayer insulating film 14 made of the silicon oxynitride film is film-formed on the surface of the gate electrode 13 by using the CVD method or the like. Specifically, as a raw gas, a mixed gas of monosilane and dinitrogen oxide, TEOS (tetraethoxysilane, Si(OC₂H₅)₄), oxygen and nitrogen, or monosilane, dinitrogen oxide and ammonia may be suitably used. After the film formation, a resist mask having a predetermined pattern is formed, and the interlayer insulating film 14 is etched via the resist mask by means of dry etching, such that contact holes are respectively formed in portions of the interlayer insulating film 14 corresponding to the high-concentration source region 11SH and the high-concentration drain region 11DH.

Next, a conductive material made of a metal material such as aluminum, titanium, titanium nitride, tantalum, or molybdenum, or an alloy mainly containing one of the above-described metal materials or the like is film-formed on the entire surface of the interlayer insulating film 14 by means of the sputtering method or the like and is patterned by the photolithography method, such that the source electrode 16S and the drain electrode 16D are formed on the contact holes of the interlayer insulating film 14. Specifically, after a photoresist is coated on the glass substrate 10 on which the conductive material is film-formed, the photoresist is exposed and developed, the conductive material is etched by dry etching, and the photoresist is removed, such that the conductive material is patterned and the source electrode 16S and the drain electrode 16D are formed. The film thickness of each of the source electrode 16S and the drain electrode 16D is preferably in a range of from 400 to 800 nm, for example.

Next, an annealing treatment is performed.

Similarly, the annealing treatment is performed under a vapor, oxygen, or hydrogen atmosphere. Thus, in the subsequent hydrogenation treatment, hydrogen is easily and effectively implanted. Further, the annealing treatment plays a role in reducing the defects (the dangling bonds) included in the gate insulating film 12, the interlayer insulating film 14, and the polycrystalline silicon film 11.

Here, the nitrogen concentration distribution in the gate insulating film 12 and the interlayer insulating film 14 after the annealing treatment will be described with reference to FIGS. 4(a) and 4(b).

If the above-described annealing treatment is conducted, the first region 15a becomes the low nitrogen concentration region and the second region 15b becomes the high nitrogen concentration region. Further, as shown in FIG. 4(b), the nitrogen concentration decreases as going away from the gate electrode 13 and is consecutively distributed. This region hardly transmits the hydrogen ions, and thus it serves as a mask in the hydrogenation treatment step. In addition, the annealing treatment plays a role in reducing the defects (the dangling bonds) included in the gate insulating film 12, the interlayer insulating film 14, and the semiconductor layer 11.

Moreover, for example, the interlayer insulating film 14 may be formed by means of the CVD method of the temperature of about 300° C. and the annealing treatment may be performed under the same condition of about 300° C. In this case, the film formation step and the annealing step of the interlayer insulating film 14 can be conducted within the same chamber, and thus a simple and consecutive process can be conducted, for example, by switching an influent gas.

Next, a hydrogenation treatment step is performed.

In this step, a hydrogen plasma treatment is performed on the polycrystalline silicon film 11 such that the termination of the dangling bond is made. Thus, the defects in the polycrystalline silicon film 11 are recovered and simultaneously damages against the polycrystalline silicon film 11, an interface between the polycrystalline silicon film 11 and the gate insulating film 12, or the gate insulating film 12, which are generated when dry etching is conducted in the source electrode 16S and the drain electrode 16D, are also recovered.

Here, the hydrogen concentration distribution, the defect density distribution, and the impurity concentration distribution in the polycrystalline silicon film 11 after the hydrogenation treatment will be described with reference to FIGS. 4(a) and 4(c).

As described above, if the hydrogen atoms are implanted via the gate insulating film 12 and the interlayer insulating film 14 having the nitrogen concentration distribution, in the high nitrogen concentration region of the second region 15b, since the hydrogen concentration is low, the defect density increases, such that the high-resistance region (a defect region) 17b is formed. On the other hand, in the low nitrogen concentration region of the first region 15a, since the hydrogen concentration is high, the defect density decreases, such that the low-resistance region 17a is formed.

Further, the low-concentration source region 11SL, the low-concentration drain region 11DL, the high-concentration source region 11SH, and the high-concentration drain region 11DH are formed in the self alignment manner in the polycrystalline silicon film 11. Thus, as described above, the defect density distribution is formed in the polycrystalline silicon film 11, and thus the respective regions 11SL, 11DL, 11SH, and 11DH have different defect densities from each other.

Therefore, a high-resistance and low-concentration region 21A which serves as the high-resistance region (the defect region) 17b and also the low-concentration source region 11SL and the low-concentration drain region 11DL is formed. Further, a low-resistance and high-concentration region 21B which serves as the low-resistance region 17a and also the high-concentration source region 11SH and the high-concentration drain region 11DH is formed. Further, the respective regions 21A and 21B are formed in the self alignment manner.

Next, as shown in FIG. 3(i), the passivation film 18 is formed. Accordingly, the manufacturing process of the semiconductor device is completed.

In this step, the passivation film 18 made of a silicon nitride film is formed to cover the source electrode 16S and the drain electrode 16D. The passivation film 18 plays a role in allowing hydrogen to remain in the hydrogenated polycrystalline silicon film 11. Therefore, for the passivation film 18, the silicon nitride film having low gas transmittance is preferably used.

As described above, in the present embodiment, by forming the nitrogen concentration distribution of the gate insulating film 12 and the oxynitride film 19, the quality of the gate insulating film 12 or the oxynitride film 19, in particular, etching selectivity can be consecutively changed. Thus, the gate insulating film 12 and the oxynitride film 19 can be allowed to remain in the peripheral portion of the gate electrode 13. Further, the gate insulating film 12 and the oxynitride film 19 in the portion spaced apart from the gate electrode 13 can be removed. Thus, the side walls 20 having the inclinations can be formed adjacent to the gate electrode 13. In addition, the impurity ions are implanted into the polycrystalline silicon film 11 with the side walls 20 formed in such a manner as a mask, and thus the low-concentration source region 11SL, the low-concentration drain region 11DL, the high-concentration source region 11SH, and the high-concentration drain region 11DH can be formed in the polycrystalline silicon film 11 according to the shapes of the side walls 20. Accordingly, the high-resistance and low-concentration region 21A and the low-resistance and high-concentration region 21B can be formed in the self alignment manner.

Further, by forming the source and drain regions in the self alignment manner in such a manner, the offleak current caused by the electric field concentration at the ends of the drain region can be reduced. Therefore, the high-resistance (defect) region 17b can be formed in the self alignment manner, and thus the variation in characteristic of the semiconductor device can be prevented from being caused.

### Third Embodiment of Manufacturing Method of Semiconductor Device

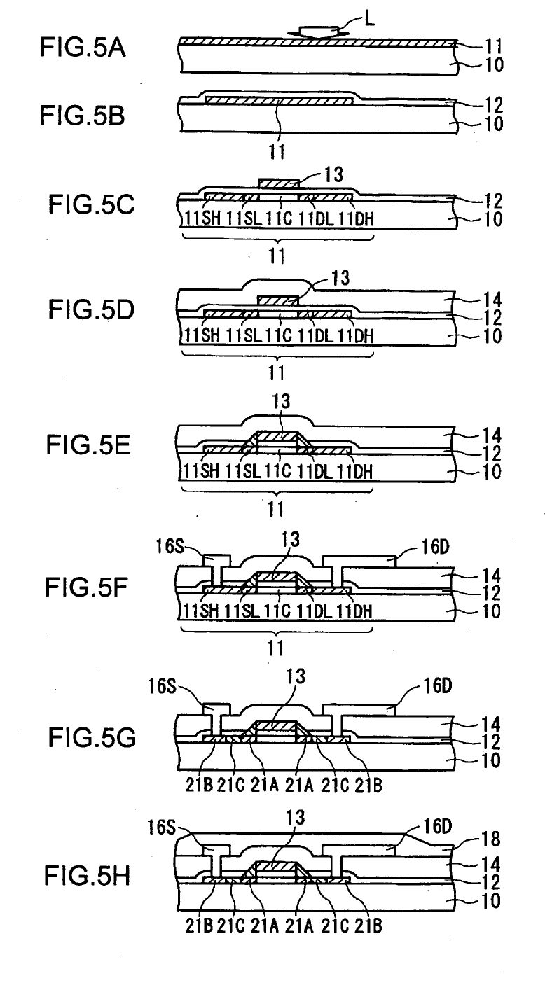

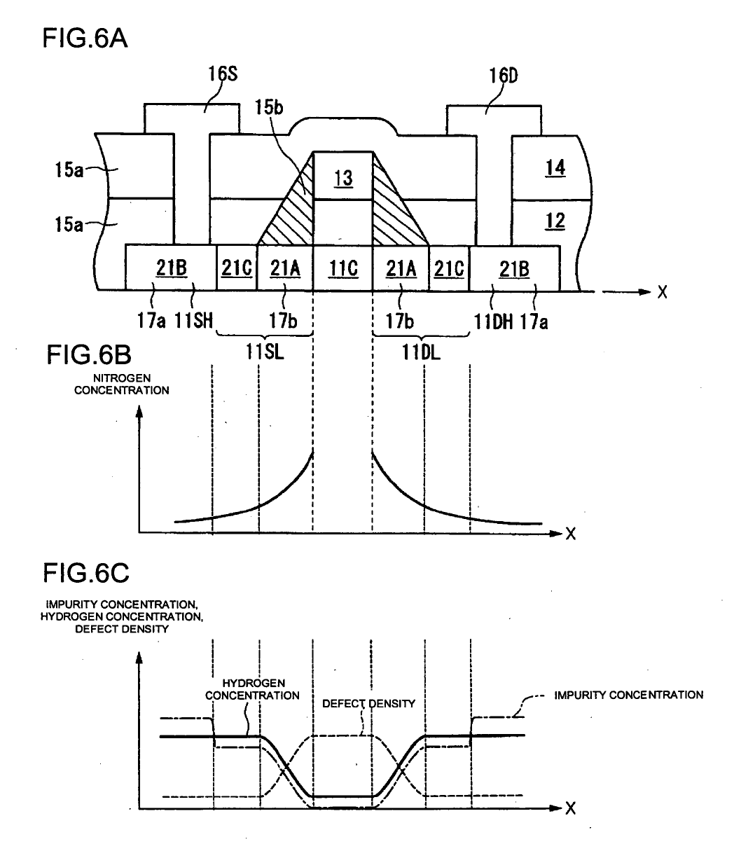

A third embodiment of the manufacturing method of a semiconductor device will be described with reference to FIGS. 5(a) to 6(c).

FIGS. 5(a) to 5(h) are process views illustrating the manufacturing method of a semiconductor device, which are expanded cross-sectional views of a semiconductor device. FIG. 6(a) is an expanded cross-sectional view of the semiconductor device which shows a peripheral portion of the gate electrode 13, FIG. 6(b) is a diagram showing a nitrogen concentration distribution corresponding to FIG. 6(a), and FIG. 6(c) is a diagram illustrating a hydrogen concentration distribution, a defect density distribution, and an impurity concentration distribution of a polycrystalline silicon film corresponding to FIG. 6(a).

Moreover, in the present embodiment, different portions from the above-described first or second embodiment will be described. Further, the same elements are represented by the same reference numerals and the descriptions of the same elements will be omitted.

First, as shown in FIGS. 5(a) to 5(c), on the glass substrate 10 on which the base protective film is formed, the polycrystalline silicon film 11, the gate insulating film 12, and the gate electrode 13 are formed.

Next, as shown in FIG. 5(c), an ion implantation into the polycrystalline silicon film 11 is performed.

In order to perform the ion implantation, a resist mask wider than the gate electrode 13 is formed, and the low-concentration impurity ions (phosphorus ions) are previously doped with a dose amount of about 0.1×10¹⁴ to about 10×10¹⁴/cm². Further, a portion where a low impurity concentration region is to be formed by means of the photolithography method is covered with a photoresist, and the high-concentration impurity ions (phosphorus ions) are doped with a dose amount of about 0.1×10¹⁵ to about 10×10¹⁵/cm². Then, by removing the photoresist, the source region, the drain region, and a high-impurity-concentration region are formed. Accordingly, the low-concentration source region 11SL, the low-concentration drain region 11DL, the high-concentration source region 11SH, and the high-concentration drain region 11DH are formed. In the portion disposed just below the gate electrode 13, the channel region 11C is formed.

Here, the width of each of the low-concentration source region 11SL and the low-concentration drain region 11DL is set to be larger than that of the second region 15b (the high nitrogen concentration region) which is to be formed later.

Next, as shown in FIG. 5(d), the interlayer insulating film (the insulating film) 14 is formed.

Next, as shown in FIG. 5(e), the annealing treatment is conducted and the nitrogen concentration distribution is formed in the gate insulating film 12 and the interlayer insulating film 14, like the above-described embodiments (see FIG. 6(b)).

Next, as shown in FIG. 5(f), the source and drain electrodes 16S and 16D are formed.

Next, as shown in FIG. 5(g), the hydrogenation treatment step is performed.

Here, the hydrogen concentration distribution, the defect density distribution, and the impurity concentration distribution in the polycrystalline silicon film 11 after the hydrogenation treatment will be described with reference to FIGS. 6(a) and 6(c).

As described above, if the hydrogen atoms are implanted via the gate insulating film 12 and the interlayer insulating film 14 having the nitrogen concentration distribution, in the high nitrogen concentration region of the second region 15b, the defect density increases, such that the high-resistance region (a defect region) 17b is formed. On the other hand, in the low nitrogen concentration region of the first region 15a, the defect density decreases, such that the low-resistance region 17a is formed. Further, the low-concentration source region 11SL, the low-concentration drain region 11DL, the high-concentration source region 11SH, and the high-concentration drain region 11DH are formed in the polycrystalline silicon film 11. Thus, as described above, the defect density distribution is formed in the polycrystalline silicon film 11, and thus the respective regions 11SL, 11DL, 1SH, and 11DH have different defect densities from each other.

In addition, the width of each of the low-concentration source region 11SL and the low-concentration drain region 11DL is set to be larger than that of the high-resistance region 17b, and thus a low-resistance and low-concentration region 21C which serves as a low-resistance region (a small defect region) and also the low-concentration source region 11SL and the low-concentration drain region 11DL is formed in the self alignment manner.

Next, as shown in FIG. 5(h), the passivation film 18 is formed.

Accordingly, the manufacturing process of the semiconductor device is completed.

As described above, in the present embodiment, the low-concentration impurity and the high-concentration impurity are sequentially implanted into the polycrystalline silicon film 11, and thus the low-concentration source region 11SL, the low-concentration drain region 11DL, the high-concentration source region 11SH, and the high-concentration drain region 11DH can be formed. Further, the respective regions 11SL, 11DL, 11SH, and 11DH can be formed to have different defect densities from each other. Further, the width of each of the low-concentration source region 11SL and the low-concentration drain region 11DL is set to be larger than that of the second region 15b (the high nitrogen concentration region), the low-resistance and low-concentration region 21C can be formed in the self alignment manner.

Further, the semiconductor device having the defect density concentration in such a manner and the low-resistance and low-concentration region 21C can be manufactured, and thus the above-described advantages can be further promoted. Specifically, the offleak current caused by the electric field concentration at the ends of the drain region can be reduced. Further, even when the deviation in positional relationship between the impurity region which is formed by implanting the impurity via the resist and the gate electrode is caused, the influence by the positional deviation can be reduced since the low defect density region is provided. Therefore, the variation in characteristic of the semiconductor device can be further suppressed. Further, the change in threshold value caused by the generation of hot electrons can be further suppressed. In addition, the semiconductor device having more stable reliability can be implemented and operational reliability of the CMOS circuits can be further enhanced.

Moreover, in the present embodiment, after the interlayer insulating film 14 is formed, the annealing treatment is conducted to form the nitrogen concentration distribution. However, the present invention is not limited to the annealing treatment step which is performed just after the interlayer insulating film 14 is formed. For example, after the source electrode 16S and the drain electrode 16D are formed, the annealing treatment may be conducted to form the nitrogen concentration distribution.

Further, in the present embodiment, the width of each of the low-concentration source region 11SL and the low-concentration drain region 11DL is wider than that of the high-resistance region 17b, and thus the low-resistance and low-concentration region 21C is formed in the self alignment manner. According to the present invention, however, the width of each of the low-concentration source region 11SL and the low-concentration drain region 11DL may be smaller than that of the high-resistance region 17b, and thus a high-resistance and high-concentration region may be formed in the self alignment manner. Further, two high-resistance regions may be formed.

Further, the present embodiment is not intended to limit the present invention, but the substitutions can be made and the improvements can be suitably added thereto based on the technical common knowledge of one of ordinary skill in the art without departing from the scope recited in the appended claims, not to be limited to the expressions thereof. For example, in the present embodiment, the n-channel type semiconductor device is exemplified, but the present invention can be applied to a p-channel type semiconductor device.

Further, in the present embodiment, the top gate type semiconductor device is described, but the present invention can be applied to the bottom gate type semiconductor device. Alternatively, in combination with a low dose region formation, a smoother resistance distribution can be formed.

(Substrate for Electro-Optical Device, Electro-Optical Device)

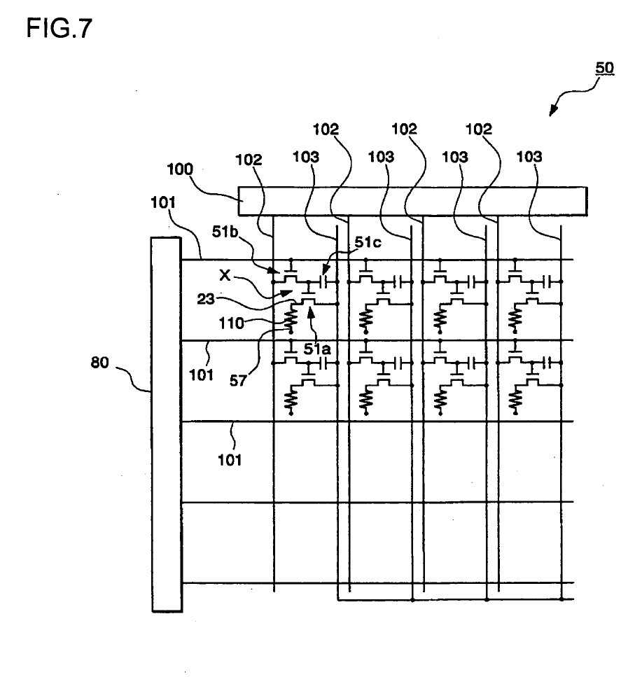

A substrate for electro-optical device and an electro-optical device will be described with reference to FIGS. 7 to 9.

Moreover, in the present embodiment, different portions from the first to third embodiments will be described. The same elements are represented by the same reference numerals and the descriptions of the same elements will be omitted.

(Organic Electroluminescent Device)

First, an organic electroluminescent device (hereinafter, referred to as an organic EL device) which is an embodiment of an electro-optical device according to the present invention will be described.

The organic EL device 50 according to the present embodiment is an active matrix type organic EL device which has thin film transistors (hereinafter, referred to as TFTs) made of the semiconductor device according to the above-described embodiments as switching elements. In particular, it is a color organic EL device comprising three types of high-molecular-weight organic light-emitting layers of R (red), G (green), and B (blue).

FIG. 7 is a schematic view showing an equivalent circuit of an organic EL device according to the present embodiment.

An organic EL device 50 has a wiring line structure comprising a plurality of scanning lines 101, a plurality of signal lines 102 extending in a direction orthogonal to the respective scanning lines 101, and a plurality of power supply lines 103 extending parallel to the respective signal lines 102. Further, in the vicinities of respective intersections of the scanning lines 101 and the signal lines 102, pixel regions X are provided.

To the signal lines 102, a data line driving circuit 100 comprising shift registers, level shifters, video lines and analog switches is connected. Further, to the scanning lines 101, a scanning line driving circuit 80 comprising shift registers and level shifters is connected. In the respective pixel regions X, a switching TFT 51b of which a gate electrode is supplied with a scanning signal via the scanning line 101, a storage capacitor 51c for storing a pixel signal which is supplied from the signal line 102 via the switching TFT 51b, a driving TFT 51a (a driving electronic element) of which a gate electrode is supplied with the pixel signal stored in the storage capacitor 51c, an anode (a pixel electrode) 52 into which a driving current flows from the power supply line 103, when being electrically connected to the power supply line 103 via the driving TFT 51a, and an electro-optical layer E interposed between the anode 52 and a cathode (a common electrode) 57 are provided. The anode 52, the cathode 57, and the electro-optical layer E constitute a light-emitting element.

According to the organic EL device 50, if the scanning line 101 is driven and the switching TFT 51b is turned on, a potential on the signal line 102 at that moment is stored in the storage capacitor 51c and, depending on a state of the storage capacitor 51c, on or off state of the driving TFT 51a is determined. And then, the current flows into the anode 52 from the power supply line 103 via a channel of the driving TFT 51a, and further the current flows into the cathode 57 via the electro-optical layer E. The electro-optical layer E emits light depending on the amount of the current flowing therein.

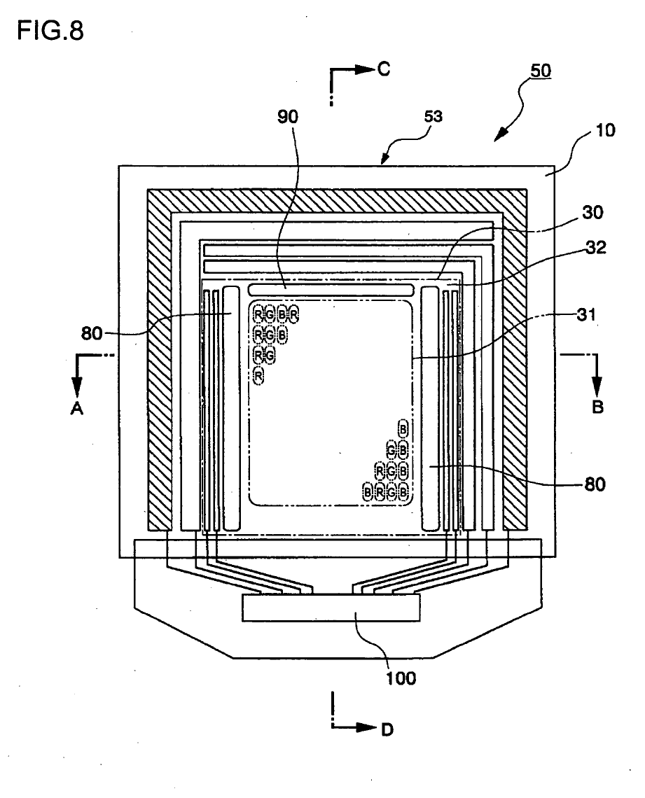

Next, a planar structure of the organic EL device 50 according to the present embodiment will be described with reference to FIG. 8.

As shown in FIG. 8, the organic EL device 50 of the present embodiment comprises a TFT substrate (a substrate for electro-optical device) 53 in which the switching TFTs are provided on an electrically insulating substrate 10. Further, the organic EL device 50 has the anodes 52 each connected to the switching TFTs of the TFT substrate 53, a pixel electrode region (not shown) on which the anodes 52 are arranged in a matrix on the substrate 10, the power supply lines 103 (see FIG. 7) arranged around the pixel electrode region and connected to the respective anodes 52, and a pixel portion 30 (in FIG. 8, within a one-dot-chain line frame) having an approximately rectangular shape in a plan view, which is positioned on at least the pixel electrode region. Further, the pixel portion 30 is divided into an actual display region 31 (in FIG. 8, within a two-dot-chain line frame) of a central portion and a dummy region 32 (a region between the one-dot-chain line and the two-dot-chain line) arranged around the actual display region 31.

In the actual display region 31, display regions R, G and B each having the pixel electrode are arranged in a matrix to be spaced apart from each other in the directions of the lines A-B and C-D. Further, at both sides of the actual display region 31 in FIG. 8, the scanning line driving circuits 80 are arranged. The scanning line driving circuits 80 are provided to position below the dummy region 32. Further, on an upper side of the actual display region 31 in FIG. 8, a test circuit 90 is arranged. The test circuit 90 is a circuit for testing operating conditions of the organic EL device 50. For example, the test circuit 90 comprises test information output means (not shown) for outputting test results to the outside. The test circuit 90 is constructed to test the quality and defects of a display device during manufacture or at the time of shipment.

Driving voltages of the scanning line driving circuits 80 and the test circuit 90 are applied from a predetermined power supply unit via driving voltage connecting portions. Further, driving control signals and driving voltages are transmitted and applied from a predetermined main driver or the like for controlling the operation of the organic EL device 50 to the scanning line driving circuits 80 and the test circuit 90 via driving control signal connecting portions or the like. Moreover, in this case, the driving control signals are instruction signals from the main driver or the like related to controls at the time when the scanning line driving circuits 80 and the test circuit 90 output signals.

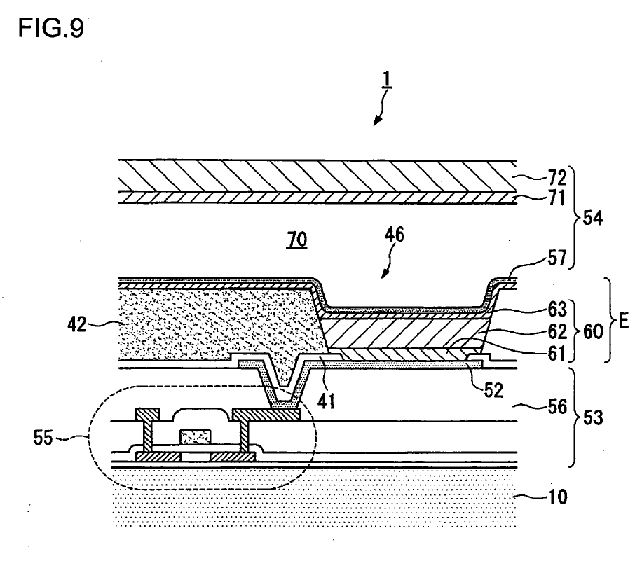

Next, a cross-sectional structure of the organic EL device 50 will be described with reference to FIG. 9.

As shown in FIG. 9, the organic EL device 50 has the TFT substrate 53, the electro-optical layer E, and a sealing layer 54. The TFT substrate 53 has the thin film transistor (the semiconductor device) 55 and an interlayer insulating film 56 on the substrate 10. Further, in the interlayer insulating film 56, the anode 52 is formed via a contact hole.

Here, the thin film transistor 55 is formed by means of the manufacturing method according to the above-described embodiment. Specifically, after the gate insulating film 12 or the interlayer insulating film 14 containing nitrogen is formed, the annealing treatment is conducted to form the nitrogen concentration distribution in the gate insulating film 12 or the interlayer insulating film 14 and the defect region 17b is formed in the semiconductor layer 11 by means of the hydrogenation treatment step. Further, in the thin film transistor 55, the low-concentration source region 11SL, the low-concentration drain region 11DL, the high-concentration source region 11SH, and the high-concentration drain region 11DH are formed. By forming the defect density distribution in each region, the high-resistance and low-concentration region 21A or the low-resistance and high-concentration region 21B is formed. Further, the low-resistance and low-concentration region 21C or the high-resistance and high-concentration region is suitably formed. In addition, these regions are formed in the self alignment manner.

Further, between the TFT substrate 53 and the electro-optical layer E, a first partition 41 and a second partition 42 are formed. The first partition 41 is made of a lyophilic material such as SiO₂. The first partition 41 covers the entire surface of the interlayer insulating film 56 and exposes a part of the anode 52. The second partition 42 is made of a resin material such as polyimide or acryl. The second partition 42 exposes the first partition 41 in a vicinity of the exposed part of the anode 52. Further, the second partition 42 preferably has liquid-repellency higher than that of the first partition 41 and is provided with a liquid droplet receiving portion 46 on the anode 52.

The electro-optical layer E has a light-emitting functional layer 60 between the anode 52 and the cathode 57.

Next, the respective elements of the light-emitting functional layer 60 and the cathode 57 will be described. The light-emitting functional layer 60 has a hole injecting layer 61, a light-emitting layer 62, and an electron injecting layer 63 which are sequentially deposited from the anode 52 toward the cathode 57.

As a material for the hole injecting layer 61, in particular, a dispersion of 3,4-polyethylenedioxythiophene/polystyrenesulfonic acid (PEDOT/PSS), that is, a dispersion in which 3,4-polyethylenedioxythiophene is dispersed into a solvent of polystyrenesulfonic acid and then water is added is used. Moreover, a material for forming the hole injecting layer 61 is not limited to the above-mentioned material, but various materials may be used. For example, a material obtained by dispersing polystyrene, polypyrrole, polyaniline, polyacetylene, or its derivative in a suitable dispersing solvent, such as polystyrenesulfonic acid described above, may be used.

As a material for the light-emitting layer 62, well-known light-emitting materials capable of emitting fluorescent light or phosphorescent light are used. Further, in order to form the organic EL device for full color display, the light-emitting layers 62 of the respective colors of R (red), G (green) and B (blue) are respectively provided for the pixel electrodes 52. As the material for the light emitting layer 62, specifically, for example, (poly)fluorene derivatives (PF), (poly)paraphenylenevinylene derivatives (PPV), polyphenylene derivatives (PP), polyparaphenylene derivatives (PPP), polyvinylcarbazole (PVK), polythiophene derivatives, or a polysilane-based material, such as polymethylphenylsilane (PMPS), are suitably used. Further, the light emitting layer may also be made of materials in which, into these high-molecular-weight materials, high-molecular-weight materials, such as perylene-based pigments, coumarin-based pigments, or rhodamine-based pigments, or low-molecular-weight materials, such as rubrene, perylene, 9,10-diphenylanthracene, tetraphenylbutadiene, Nile red, coumalin 6 or quinacridone are doped.

Further, as a material for the red light-emitting layer 62, for example, MEHPPV (poly(3-methoxy 6-(3-ethylhexyl)paraphenylenevinylene)) may be used, and as a material for the green light-emitting layer 62, for example, a mixture solution of polydioctylfluorene and F8BT (an alternating copolymer of dioctylfluorene and benzothiadiazole) may be used. Further, as a material for the blue light-emitting layer 62, for example, polydioctylfluorene may be used. Further, as regards the light-emitting layer 62, the thickness is not particularly limited, and, for each color, the desired film thickness may be adjusted.

The electron injecting layer 63 is formed on the light-emitting layer 62. A material of the electron injecting layer 63 is suitably selected according to the material of the light-emitting layer 62. As a specific material, a fluoride of an alkali metal material such as LiF (lithium fluoride), NaF (sodium fluoride), KF (potassium fluoride) RbF (rubidium fluoride) or CsF (cesium fluoride), or an oxide of an alkali metal material such as Li₂O (lithium oxide), Na₂O (sodium oxide) is suitably used. Further, the thickness of the electron injecting layer 63 is preferably set to about 0.5 nm to 10 nm.

The cathode 57 has an area wider than the total area of the electron injecting layer 63 to cover the electron injecting layer 63. The cathode 57 has a first cathode made of a metal material having low work function and provided on the electron injecting layer 63 and a second cathode provided on the first cathode to protect the first cathode. As the metal material having low work function for the first cathode, in particular, a metal material having work function of 3.0 eV or less is preferable. Specifically, Ca (work function; 2.6 eV), Sr (work function; 2.1 eV) or Ba (work function; 2.5 eV) is suitably used. The second cathode is provided to cover the first cathode so as to protect it from oxygen or moisture and increase conductance of the entire cathode 57. As a material for the second cathode, any material having chemical stability and relatively low work function may be used without limit. For example, an arbitrary material such as a metal material or an alloy may be used. Specifically, Al (aluminum) or Ag (silver) is suitably used.

Moreover, the organic EL device 1 having the above-mentioned configuration has a bottom gate structure, but the present invention is not limited to this structure. For example, the organic EL device 1 may be applied to a so-called top gate structure in which emitted light is derived from a sealing substrate 72 side.

The top gate type organic EL device has a configuration in which emitted light is derived from the sealing substrate 72 at an opposite side to the substrate 10, and thus any one of a transparent substrate and a non-transparent substrate may be used. As the non-transparent substrate, for example, in addition to one in which an insulation treatment such as surface oxidization is performed on ceramic such as alumina, or a metal sheet such as stainless steel, thermosetting resin or thermoplastic resin is exemplified.

Further, the sealing layer 54 has a nitrogen gas filled layer 70, a getter agent 71, and the sealing substrate 72. Here, the getter agent 71 is attached to the inside of the sealing substrate 72 and absorbs moisture or oxygen. As such, since the sealing layer 54 has the nitrogen gas filled layer 70 and the getter agent 71, moisture or oxygen is suppressed to be penetrated inside the organic EL device 50, and thus the organic EL device 50 has long life span.

As described above, in the present embodiment, the organic EL device 50 has the thin film transistors 55 as the switching elements, and thus the offleak current caused by the electric field concentration at the ends of the drain region can be reduced. Further, the high-resistance region 17b is formed in the self alignment manner, and thus it has an advantage in that the variation in characteristic of the semiconductor device can be prevented from being caused. Further, the change in threshold value caused by the generation of hot electrons can be prevented. Further, since the high nitrogen concentration region is provided above the polycrystalline silicon film 11, the hydrogen atoms (terminating the dangling bond states) of the polycrystalline silicon film 11 are hardly separated from the polycrystalline silicon film 11, thereby obtaining the blocking effect. As a result, the semiconductor device having more stable reliability can be implemented. Further, the oversaturated hydrogen atoms can be prevented from being implanted into the gate insulating film 12 at the time of the hydrogenation treatment. Thus, in particular, in a P-type semiconductor device, when a negative bias voltage is applied to the gate electrode, the threshold value can be prevented from being enhanced due to the hole implantation effect into the gate insulating film 12. Therefore, operational reliability of the CMOS circuits can be enhanced. Further, by adopting the semiconductor device according to the present invention for the driving TFT 51a, an OFF current can be controlled. In addition, since it is formed in the self alignment manner, the variation in characteristic of the TFT is small. As a result, the organic EL device having uniform brightness in the display region can be implemented.

Moreover, in the present embodiment, the TFT substrate 53 having the thin film transistor 55 and the organic EL device 50 are described, but the present invention is not limited to this configuration. For example, the TFT substrate 53 may be adopted for a liquid crystal device.

(Electronic Apparatus)

Next, an example of an electronic apparatus having the above-described organic EL device will be described.

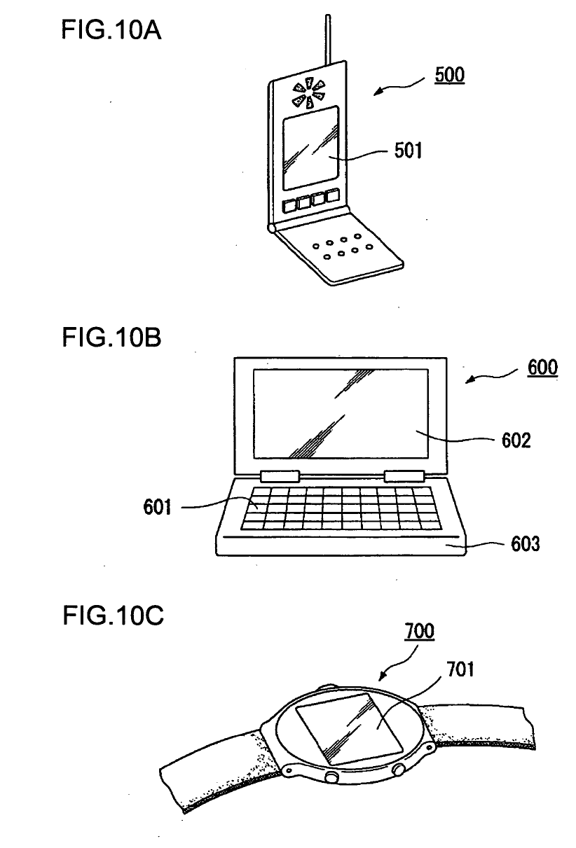

FIG. 10(a) is a perspective view showing an example of a cellular phone. In FIG. 10(a), reference numeral 500 denotes a cellular phone main body and reference numeral 501 denotes a display unit having the organic EL device.

FIG. 10(b) is a perspective view showing an example of a portable information processing device such as a word processor, a personal computer, or the like. In FIG. 10(b), reference numeral 600 denotes an information processing device, reference numeral 601 denotes an input unit such as a keyboard or the like, reference numeral 603 denotes an information processing device main body, and reference numeral 602 denotes a display unit having the organic EL device.

FIG. 10(c) is a perspective view showing an example of a wristwatch-type electronic apparatus. In FIG. 10(c), reference numeral 700 denotes a watch main body, reference numeral 701 denotes an EL display unit having the organic EL device. The electronic apparatuses shown in FIGS. 10(a) to 10(c) have the organic EL device in the above-described embodiments respectively, and thus they have favorable display quality.

Moreover, an electronic apparatus is not limited to the above-mentioned apparatuses. That is, the present invention can be applied to various electronic apparatuses. For example, the present invention can be applied to electronic apparatuses such as a desktop computer, a liquid crystal projector, a multimedia personal computer (PC) and an engineering workstation (EWS), a pager, a word processor, a television, a viewfinder-type or monitor-direct-view-type video recorder, an electronic organizer, an electronic calculator, a car navigation device, a POS terminal, a device having a touch panel, and so on.

1. A manufacturing method of a semiconductor device comprising:
an electrode formation step of forming an electrode above a semiconductor layer;
an insulating film formation step of forming an insulating film containing nitrogen above the semiconductor layer; and
a heat treatment step of performing a heat treatment under an atmosphere containing vapor, oxygen, or hydrogen to form a nitrogen concentration distribution in the insulating film.

2. The manufacturing method of a semiconductor device according to claim 1, further comprising:
after the heat treatment step, a hydrogenation treatment step of implanting hydrogen atoms into the semiconductor layer.

3. The manufacturing method of a semiconductor device according to claim 1,
wherein the hydrogenation treatment step is a hydrogen plasma treatment or hydrogen diffusion treatment.

4. The manufacturing method of a semiconductor device according to claim 1, further comprising:
after the electrode formation step, an impurity implantation step of implanting an impurity into the semiconductor layer.

5. The manufacturing method of a semiconductor device according to claim 4,
wherein the impurity implantation step implants a first concentration of impurity and a second concentration of impurity into the semiconductor layer to respectively form a first concentration impurity region adjacent to a channel region of the semiconductor layer and a second concentration impurity region adjacent to the first concentration impurity region.

6. The manufacturing method of a semiconductor layer according to claim 1, further comprising:
after the heat treatment step,
a side wall portion formation step of etching the insulating film to form side wall portions adjacent to the electrode; and
an impurity implantation step of implanting an impurity into the semiconductor layer with the side wall portions as a mask.

7. The manufacturing method of a semiconductor device according to claim 6,
wherein the impurity implantation step implants a first concentration of impurity and a second concentration of impurity into the semiconductor layer according to the shapes of the side wall portions.

8. The manufacturing method of a semiconductor device according to claim 1,
wherein the electrode is one of a gate electrode and a source or drain electrode.

9. A semiconductor device comprising an electrode and an insulating film containing nitrogen above a semiconductor layer,
wherein a nitrogen concentration in the insulating film is symmetrically distributed into both side portions of the electrode.

10. The semiconductor device according to claim 9,
wherein the nitrogen concentration in the insulating film is high in a peripheral portion of the electrode and low in a portion spaced apart from the electrode, and the nitrogen concentration in the insulating film is consecutively distributed.

11. A substrate for electro-optical device comprising, on a substrate, the semiconductor device as claimed in claim 9.

12. An electro-optical device comprising the substrate for electro-optical device as claimed in claim 11.

13. An electronic apparatus comprising the electro-optical device as claimed in claim 12.
